(19) United States
(12) Patent Application Publication
(10) Pub. No.: US 2026/0089959 A1
(43) Pub. Date: Mar. 26, 2026

(54) SEMICONDUCTOR DEVICE AND ELECTRONIC SYSTEM INCLUDING SEMICONDUCTOR DEVICE

(71) Applicant: Samsung Electronics Co., Ltd., Suwon-si (KR)

(72) Inventors: Kohji Kanamori, Suwon-si (KR); Sanghun Chun, Suwon-si (KR)

(21) Appl. No.: 19/053,012

(22) Filed: Feb. 13, 2025

(30) Foreign Application Priority Data
Sep. 26, 2024 (KR) 10-2024-0131034

(51) Int. Cl. H10B 43/35; H10B 41/10; H10B 41/27; H10B 41/35; H10B 43/10; H10B 43/27

(52) U.S. Cl. CPC H10B 43/35; H10B 41/10; H10B 41/27; H10B 41/35; H10B 43/10; H10B 43/27

(57) ABSTRACT

Provided is a semiconductor device including: a gate stack structure including a plurality of interlayer insulating layers and a plurality of gate electrodes that are alternately stacked; a channel structure that extends into the gate stack structure; a plurality of first semiconductor patterns at one end of the channel structure and each of the plurality of first semiconductor patterns including a P-doped region and an undoped region; an N-doped region between adjacent ones of the first semiconductor patterns; a blocking pattern between the P-doped region and the N-doped region; and a common source electrode on respective surfaces of each of the plurality of first semiconductor patterns and the N-doped region.

### CROSS-REFERENCE TO RELATED APPLICATION

This application claims priority to and the benefit of Korean Patent Application No. 10-2024-0131034 filed in the Korean Intellectual Property Office on Sep. 26, 2024, the entire contents of which are incorporated herein by reference.

### BACKGROUND OF THE INVENTION

The present disclosure relates to a semiconductor device and an electronic system including a semiconductor device.

An electronic system that requires data storage may need a semiconductor device capable of storing a large amount of data. Accordingly, a method for increasing a data storage capacity of the semiconductor device is being studied. For example, as one of the methods for increasing the data storage capacity of the semiconductor device, the semiconductor device is proposed to include memory cells arranged three-dimensionally instead of two-dimensionally.

### SUMMARY OF THE INVENTION

The present disclosure attempts to provide a semiconductor element securing improved reliability and reduced misalignment during a manufacturing process, and an electronic system including the same.

According to some embodiments, provided is a semiconductor device including a gate stack structure including a plurality of interlayer insulating layers and a plurality of gate electrodes that are alternately stacked; a channel structure that extends into the gate stack structure; a plurality of first semiconductor patterns at one end of the channel structure and each of the plurality of first semiconductor patterns including a P-doped region and an undoped region; an N-doped region between adjacent ones of the first semiconductor patterns; a blocking pattern between the P-doped region and the N-doped region; and a common source electrode on respective surfaces of each of the plurality of first semiconductor pattern and the N-doped region.

According to some embodiments, provided is a method for manufacturing a semiconductor device, the method including forming an N-doped region on a substrate; forming an etch stopper by etching a portion of the N-doped region; forming a gate stack structure on the N-doped region and the etch stopper; forming a channel hole that extends into the gate stack structure and overlapping the etch stopper; removing the etch stopper; forming a gate dielectric layer and a channel layer in a region from which the channel hole and the etch stopper are removed; forming a groove by removing a material filling the substrate and the etch stopper; forming a blocking pattern on a side surface of the groove; and forming an undoped region and a P-doped region in the groove.

According to some embodiments, provided is a semiconductor device including a substrate including an N-doped region and a plurality of first semiconductor patterns in the N-doped region, a gate stack structure including a plurality of interlayer insulating layers and a plurality of gate electrodes that are alternately stacked on the substrate, and a channel structure that extends into the gate stack structure and overlaps the first semiconductor pattern. The first semiconductor pattern includes a P-doped region and an undoped region, and the first semiconductor pattern includes a blocking pattern between the P-doped region and the N-doped region.

The embodiments set forth above may provide the semiconductor element securing the improved reliability and the reduced misalignment during the manufacturing process, and the electronic system including the same.

### BRIEF DESCRIPTION OF THE DRAWINGS

FIG. 1 is a schematic plan view of a semiconductor element according to some embodiments.

FIG. 2 is a cross-sectional view taken along line A-A′ in FIG. 1.

FIG. 3 is an enlarged cross-sectional view of region A in FIG. 2.

FIG. 4 shows a flow direction of a hole current for erasing and a direction of an electron current flowing in channel inversion during a read operation in the same region as FIG. 3.

FIGS. 5 through 25 show a manufacturing process according to some embodiments of the present disclosure.

FIG. 26 is a view schematically showing an electronic system including a semiconductor device according to some embodiments.

FIG. 27 is a perspective view schematically showing the electronic system including a semiconductor device according to some embodiments.

FIG. 28 conceptually shows a region cut along line I-I′ of a semiconductor package in FIG. 27.

### DETAILED DESCRIPTION OF THE EMBODIMENTS

Hereinafter, embodiments of the present disclosure are described in detail with reference to the accompanying drawings so that those skilled in the art to which the present disclosure pertains may easily practice the present disclosure. However, the present disclosure may be implemented in various different forms and is not limited to the embodiments provided herein.

The thicknesses of several layers and regions are exaggerated in the drawings in order to clearly represent several layers and regions. Like reference numerals designate like elements throughout the specification. It will be understood that when an element such as a layer, a film, a region, or a substrate is referred to as being “on” another element, it may be directly on another element or may have another element interposed therebetween. On the other hand, when an element is referred to as being “directly on”another element, there is no third element interposed therebetween.

Hereinafter, a semiconductor device and an electronic system according to the embodiments of the present disclosure are described in detail with reference to the drawings. Herein, the terms indicating order, such as first, second, etc., are used to distinguish elements having the same/similar functions, and the ordinal numbers may be interchanged according to the order in which the terms are mentioned. The term “and/or”includes any and all combinations of one or more of the associated listed items.

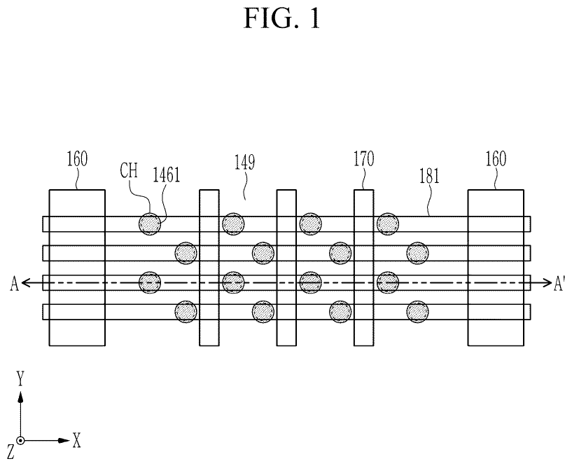

The following description describes the semiconductor device according to some embodiments with reference to FIGS. 1 to 5.

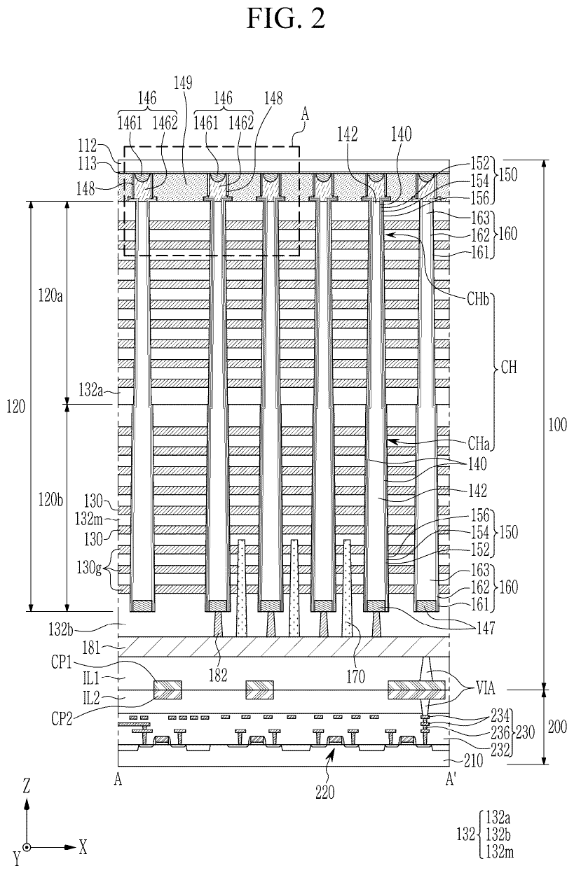

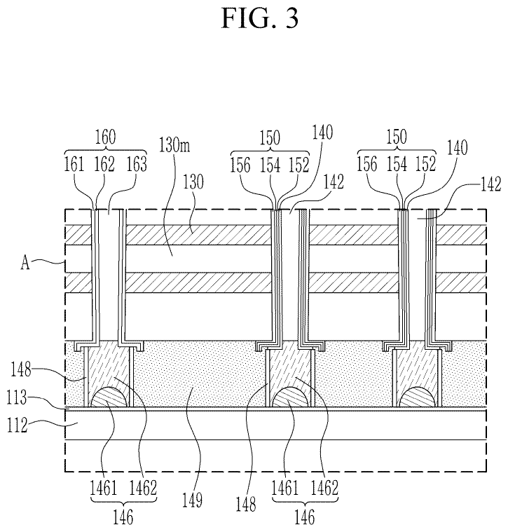

FIG. 1 is a schematic plan view of a semiconductor element according to some embodiments. FIG. 2 is a cross-sectional view taken along line A-A′ in FIG. 1. FIG. 3 is an enlarged cross-sectional view of region A in FIG. 2. For convenience of description, FIG. 3 shows region A in FIG. 2 by flipping its top and bottom.

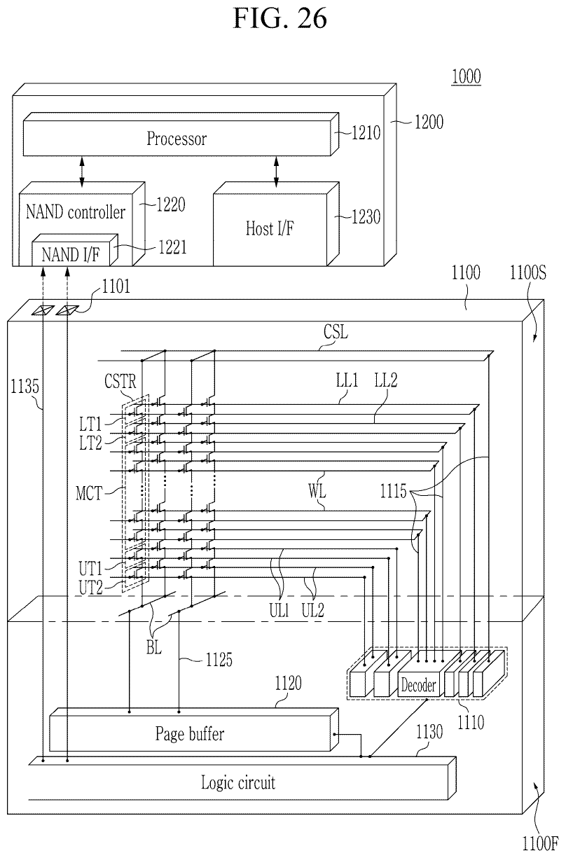

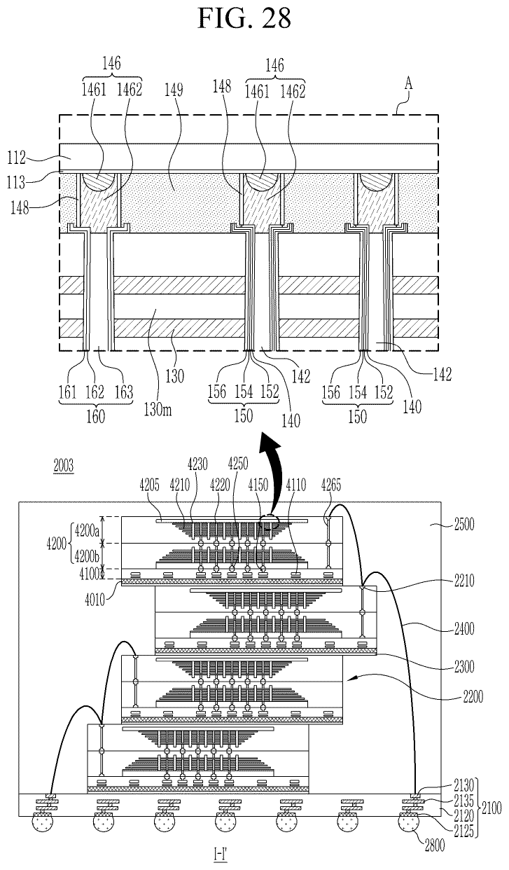

Referring to FIGS. 1 to 3, the semiconductor device according to some embodiments may include a cell region 100 provided with a memory cell structure and a circuit region 200 provided with a peripheral circuit structure that controls an operation of the memory cell structure. As an example, the circuit region 200 and the cell region 100 may respectively be portions corresponding to the first structure 1100F and second structure 1100S of a semiconductor device 1100 included in an electronic system 1000 shown in FIG. 26. In some embodiments, the circuit region 200 and the cell region 100 may respectively be portions including the first structure 4100 and second structure 4200 of a semiconductor chip 2200 shown in FIG. 28.

Here, the circuit region 200 may include the peripheral circuit structure formed on a first substrate 210, and the cell region 100 may include a gate stack structure 120 and a channel structure CH as the memory cell structure. In some embodiments, the cell region 100 may be disposed on the circuit region 200. Accordingly, an area corresponding to the circuit region 200 may not need to be secured separately from the cell region 100, thus reducing an area of the semiconductor device. However, some embodiments is not limited thereto, and the circuit region 200 may be disposed next to the cell region 100. some embodiments may be modified in various other ways.

The circuit region 200 may include the first substrate 210, a circuit element 220 and a first wiring part 230, formed on the first substrate 210.

The first substrate 210 may be a semiconductor substrate including a semiconductor material. For example, the first substrate 210 may be the semiconductor substrate made of the semiconductor material, or may be the semiconductor substrate in which a semiconductor layer is formed on a base substrate. As an example, the first substrate 210 may include monocrystalline or polycrystalline silicon, epitaxial silicon, germanium, silicon-germanium, silicon-on-insulator (SOI), or germanium-on-insulator (GOI).

The circuit element 220 formed on the first substrate 210 may include various circuit elements that control the operation of the memory cell structure disposed in the cell region 100. As an example, the circuit element 220 may configure the peripheral circuit structure such as a decoder circuit 1110 (in FIG. 26), a page buffer 1120 (in FIG. 26), a logic circuit 1130 (in FIG. 26), or the like.

The circuit element 220 may include, for example, a transistor, and is not limited thereto. For example, the circuit element 220 may include not only an active element such as the transistor, but also a passive element such as a capacitor, a resistor, or an inductor.

The first wiring part 230 disposed on the first substrate 210 may be electrically connected to the circuit element 220. In some embodiments, the first wiring part 230 may include a plurality of wiring layers 234 spaced apart from each other while having a wiring insulating layer 232 therebetween and connected to each other to form a desired path by a contact via 236. The wiring layer 234 or the contact via 236 may include various conductive materials, and the wiring insulating layer 232 may include various insulating materials.

The circuit region 200 may include a second insulating layer IL2 disposed on the first wiring part 230. The second insulating layer IL2 may include a second pad CP2, and the second pad CP2 of the second insulating layer IL2 and the wiring layer 234 may be connected to each other through a via VIA. The second pad CP2 may include copper, and is not limited thereto.

The cell region 100 may include the gate stack structure 120 and the channel structure CH. The cell region 100 may include a structure for connecting the gate stack structure 120 and/or the channel structure CH, formed in the cell region 100, to the circuit region 200 or an external circuit.

The cell region 100 may include a first insulating layer IL1 disposed in a portion in contact with the circuit region 200. The first insulating layer IL1 may include a first pad CP1, and the first pad CP1 of the first insulating layer IL1 and a bit line 181 may be connected to each other through the via VIA. The first pad CP1 may include copper, and is not limited thereto. As shown in FIG. 2, the first pad CP1 and the second pad CP2 may be in direct contact with each other. That is, the cell region 100 and the circuit region 200 may be connected to each other through the first pad CP1 and the second pad CP2. Each of the first pad CP1 and the second pad CP2 may include copper, and is not limited thereto.

The cell region 100 may include the gate stack structure 120 including a cell insulating layer 132 and a gate electrode 130 that are alternately stacked, and the channel structure CH that extends in a third direction (Z direction) by extending into or passing through the gate stack structure 120.

The cell insulating layer 132 may include an interlayer insulating layer 132m disposed between the two adjacent gate electrodes 130 in each of a plurality of gate stack structures 120a and 120b, and an interface insulating layer 132a or 132b disposed on one surface of each of the plurality of gate stack structures 120a and 120b. In some embodiments, the thicknesses of the plurality of cell insulating layers 132 may not all be the same as each other. For example, the thickness of the interface insulating layer 132a or 132b may be greater than the thickness of the interlayer insulating layer 132m.

The gate electrode 130 may include various conductive materials. For example, the gate electrode 130 may include a metal material (e.g., tungsten (W), copper (Cu), aluminum (Al), or molybdenum (Mo)), polycrystalline silicon, a metal nitride (e.g., titanium nitride (TiN) or tantalum nitride (TaN)), or a combination thereof. The cell insulating layer 132 may include various insulating materials. For example, the cell insulating layer 132 may include silicon oxide, silicon nitride, silicon oxynitride, a low-k material having a lower dielectric constant than silicon oxide, or a combination thereof.

In some embodiments, the channel structure CH may be formed by passing through the gate stack structure 120 and extending in a direction intersecting the first substrate 210 (for example, a direction perpendicular to the first substrate 210, that is, the Z axis direction in the drawing).

Referring to FIGS. 2 and 3 simultaneously, the channel structure CH may include a channel layer 140 and a gate dielectric layer 150 disposed on the channel layer 140 between the gate electrode 130 and the channel layer 140. The channel structure CH may further include a core insulating layer 142 disposed in the channel layer 140, or may not include the core insulating layer 142 in another example. The channel structure CH may include a first semiconductor pattern 146 and a second semiconductor pattern 147 each disposed at one end of the channel structure CH. The gate dielectric layer 150 disposed between the gate electrode 130 and the channel layer 140 may include a tunneling layer 152, a charge storage layer 154, and a blocking layer 156 which are sequentially formed on the channel layer 140.

Each channel structure CH may form one memory cell string, and the plurality of channel structures CH may be arranged in rows and columns on a plane while being spaced apart from each other. For example, the plurality of channel structures CH may be arranged on the plane in any of various shapes such as a grid shape, a zigzag shape, and the like. The channel structure CH may have a columnar shape. However, some embodiments are not limited thereto, and the arrangement structure, shape, or the like of the channel structure CH may be variously modified.

The channel layer 140 may include the semiconductor material, for example, monocrystalline silicon or polycrystalline silicon. The core insulating layer 142 may include various insulating materials. For example, the core insulating layer 142 may include silicon oxide, silicon nitride, silicon oxynitride, or a combination thereof.

The tunneling layer 152 may include the insulating material (e.g., silicon oxide or silicon oxynitride) that allows charge tunneling. The charge storage layer 154 may be used as a data storage region, and the charge storage layer 154 may include polycrystalline silicon, silicon nitride, or the like. The blocking layer 156 may include the insulating material that may prevent undesirable charge inflow into the gate electrode 130. For example, the blocking layer 156 may include silicon oxide, silicon nitride, silicon oxynitride, a high-k material having a higher dielectric constant than silicon oxide, or a combination thereof.

However, the material, stack structure, or the like of each of the channel layer 140, the core insulating layer 142, and the gate dielectric layer 150 may be modified in various ways, and some embodiments is not limited thereto.

As shown in FIG. 2, the first semiconductor pattern 146 and the second semiconductor pattern 147 may be disposed at both the ends of the channel structure CH to be electrically connected to the channel layer 140.

The second semiconductor pattern 147 may be disposed in a region where the core insulating layer 142 is removed, and may be in contact with the channel layer 140. The second semiconductor pattern 147 may include epitaxial silicon, epitaxial germanium, polycrystalline silicon, monocrystalline silicon, polycrystalline germanium, or monocrystalline germanium, which is either doped or undoped with a dopant. For example, the second semiconductor pattern 147 may include polycrystalline silicon doped with N+, and, as described below, the second semiconductor pattern 147 may be connected to the bit line 181, and the first semiconductor pattern 146 may be connected to a common source electrode 112.

Referring to FIG. 3, the first semiconductor pattern 146 may include a P-doped region 1461 and an undoped region 1462. As described separately below, the P-doped region 1461 may be a region doped with P and electrically connected to the common source electrode 112, and the undoped region 1462 may be a region where undoped crystalline silicon is disposed. FIG. 3 shows a common source electrode-interface layer 113 disposed on the common source electrode 112, which is only an example, and the common source electrode-interface layer 113 may be omitted in some embodiments.

The common source electrode-interface layer 113 may include TiN, and is not limited thereto. The common source electrode 112 may include tungsten, for example, and is not limited thereto.

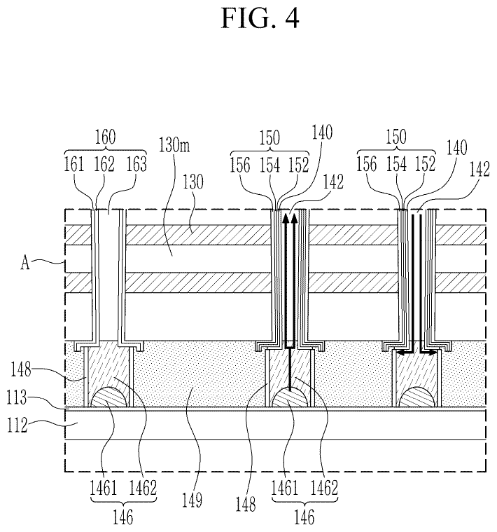

As shown in FIG. 3, the P-doped region 1461 may be disposed between the undoped region 1462 and the common source electrode 112. This structure may be derived by forming the P-doped region 1461 in a self-aligned manner, which is described separately below. As shown in FIGS. 2 and 3, the semiconductor device according to this embodiment may have the P-doped region 1461 disposed below each channel structure CH. In addition, as described separately below, an N-doped region 149 may be disposed between the respective P-doped regions 1461, and a blocking pattern 148 may be disposed between the N-doped region 149 and the P-doped region 1461. Therefore, the semiconductor device according to this embodiment may effectively perform a bulk erase operation. A specific effect of the operation is described below with reference to FIGS. 3 and 4.

Referring again to FIG. 2, in some embodiments, the gate stack structure 120 may include the plurality of gate stack structures 120a and 120b that are sequentially stacked. The number of the stacked gate electrodes 130 may thus be increased, thereby increasing the number of memory cells in a stable structure. The drawing shows the gate stack structure 120 including the first and second gate stack structures 120a, 120b. However, some embodiments is not limited thereto. The gate stack structure 120 may include one gate stack structure or may include three or more gate stack structures.

As described above, when the plurality of gate stack structures 120a and 120b are provided, the channel structure CH may have a plurality of channel structures CHa and CHb respectively extending into or passing through the plurality of gate stack structures 120a and 120b. The plurality of channel structures CHa and CHb may be respectively connected to each other. Each of the plurality of channel structures CHa and CHb may have a slanted side that becomes narrower as the structure approaches the common source electrode 112, based on an aspect ratio, when viewed from its cross section, and a bent part may be formed due to a width difference at a connection portion between the plurality of channel structures CHa and CHb. As another example, each of the plurality of channel structures CHa and CHb may have the slanted side continuously connected without the bent part. FIG. 2 shows that the gate dielectric layer 150, channel layer 140, and core insulating layer 142 of each of the plurality of channel structures CHa and CHb extend from one another to form an integral structure. However, some embodiments are not limited thereto, and the gate dielectric layer 150, channel layer 140, and core insulating layer 142 of each of the plurality of channel structures CHa and CHb may be formed separately from each other and then electrically connected to each other. In addition, a separate channel pad may be further provided on the connection portion between the plurality of channel structures CHa and CHb. In this way, some embodiments are not limited to a form of the plurality of channel structures CHa and CHb.

In some embodiments, the gate stack structure 120 may be partitioned into a plurality of parts on the plane by a separation structure 160 that extends in the direction intersecting the first substrate 210 (for example, the direction perpendicular to the first substrate 210, that is, the Z axis direction in the drawing) to pass through the gate stack structure 120. In addition, a separation pattern 170 may be formed on one side of the gate stack structure 120. Referring to FIG. 1 simultaneously, the plurality of separation structures 160 and/or the separation patterns 170 may be provided on the plane, and extend in a second direction (Y axis direction in the drawing) to be spaced apart from each other by a predetermined distance in a first direction (X axis direction in the drawing) intersecting the second direction.

By the separation structure 160, the plurality of gate stack structures 120 may each extend on the plane in the second direction (Y axis direction in the drawing) to be spaced apart from each other by a predetermined distance in the first direction (X axis direction in the drawing). The gate stack structure 120 partitioned by the separation structure 160 may configure one memory cell block. However, some embodiments is not limited thereto, and a range of the memory cell blocks is not limited thereto.

For example, the separation structure 160 may pass through the gate stack structure 120, and the separation pattern 170 may separate only one or some of the plurality of gate electrodes 130 from each other.

The separation pattern 170 may be disposed between the separation structures 160. Each of the plurality of separation patterns 170 may be disposed between the adjacent separation structures 160. Here, the gate electrode 130 separated by the separation pattern 170 may be referred to as a selection gate electrode 130g. Here, the selection gate electrode 130g may be a string selection gate electrode that selects a string, and the separation pattern 170 may be a string separation pattern that separates the string. In some embodiments, the selection gate electrode 130g may further include the gate electrode other than a string selection gate that selects the string.

As an example, the separation structure 160 is shown as having a slanted side whose width is gradually increased as the structure approaches the common source electrode 112 due to a high aspect ratio when viewed from its cross section, and some embodiments are not limited thereto. In addition, this embodiment shows that the separation structure 160 includes the bent part at the connection portion between the plurality of gate stack structures 120a and 120b. However, the separation structure 160 may not include the bent part at the connection portion between the plurality of gate stack structures 120a and 120b.

The separation structure 160 or the separation pattern 170 may be partially or completely filled with the various insulating materials. For example, the separation structure 160 or the separation pattern 170 may include the insulating material such as silicon oxide, silicon nitride, or silicon oxynitride. FIGS. 2 and 3 show that the separation structure 160 is partially or completely filled with a first layer 161, a second layer 162, a third layer 163, the first semiconductor pattern 146, and the second semiconductor pattern 147, and is not limited thereto. In some embodiments, the first layer 161 of the separation structure 160 may include silicon oxide, the second layer 162 may include silicon nitride, and the third layer 163 may include silicon oxide, which is only an example, and the present disclosure is not limited thereto.

In addition, as shown in FIG. 2, a contact via 182 may be disposed between the channel structure CH and the bit line 181. Referring to FIG. 1, the bit line 181 may extend in the first direction (X axis direction in the drawing) intersecting the second direction in which the gate electrode 130 extends. The bit line 181 may be electrically connected to the channel structure CH through the contact via 182.

Referring to FIG. 2, the common source electrode 112 may be disposed on the other surface of the gate stack structure 120. The common source electrode 112 may be connected to the first semiconductor pattern 146 of the channel structure CH. The common source electrode 112 may be provided as a common source line (e.g., CSL in FIG. 26) of a nonvolatile memory device. The common source electrode 112 may include, for example, polycrystalline silicon doped with impurities, a metal, or a combination thereof, and is not limited thereto. As shown in FIG. 2, the common source electrode-interface layer 113 may be disposed between the common source electrode 112 and the channel structure CH. The common source electrode 112 may include tungsten, and the common source electrode-interface layer 113 may include TiN. In some embodiments, the common source electrode-interface layer 113 may be omitted.

Although not shown in FIG. 2, another semiconductor structure including the cell region may be stacked on the common source electrode 112. In this case, the common source electrode 112 of the semiconductor structure shown in FIG. 2 and the common source electrode of the additionally stacked semiconductor structure may be stacked to face each other, and the common source electrodes 112 of the respective semiconductor structures may be connected to each other. This connection may be made using a copper pad. This connection form is an example, a schematic connection form is shown as a 2-1 structure 4200a and a 2-2 structure 4200b in FIG. 28, and is not limited thereto.

Hereinafter, the description describes a connection form of the common source electrode 112 and the channel structure CH below with reference to FIG. 3. For convenience of description, FIG. 3 shows region A in FIG. 2 by flipping its top and bottom.

Referring to FIG. 3, the N-doped region 149 and the first semiconductor pattern 146 may be disposed on one surface of the common source electrode 112. The first semiconductor pattern 146 may include the P-doped region 1461 and the undoped region 1462. The P-doped region 1461 may be a region doped with P and electrically connected to the common source electrode 112, and the undoped region 1462 may be a region where undoped crystalline silicon is disposed.

Referring to FIG. 1 and FIG. 3 simultaneously, a remaining region in FIG. 1 where the channel structure CH and the P-doped region 1461 are not disposed may be the N-doped region 149. That is, the channel structure CH may be disposed in the N-doped region 149, and the P-doped region 1461 may overlap the channel structure CH.

Referring to FIGS. 1 to 3, the P-doped region 1461 may have a plan view dimension or planar diameter smaller than (i.e., less than) or equal to a plan view dimension or planar diameter of the widest portion of the channel structure. In addition, the P-doped region 1461 may have the plan view dimension or planar diameter larger than (i.e., greater than) a plan view dimension or planar diameter of a portion of the channel structure that is in contact with the first semiconductor pattern 146. FIG. 1 shows a cross section of the widest portion of the channel structure CH. As shown in FIG. 1, the P-doped region 1461 may have the plan view dimension or planar diameter smaller than the plan view dimension or planar diameter of the widest portion of the channel structure CH.

As shown in FIG. 3, the blocking pattern 148 may be disposed between the P-doped region 1461 and the N-doped region 149. Therefore, the P-doped region 1461 and the N-doped region 149 may not be in direct contact with each other. The blocking pattern 148 may include silicon oxide, and is not limited thereto. The blocking pattern 148 may include the insulating material.

However, referring to FIG. 3, the blocking pattern 148 may not completely electrically insulate the first semiconductor pattern 146 and the N-doped region 149 from each other. As shown in FIG. 3, the blocking pattern 148 may be spaced apart from the gate dielectric layer 150 and may not be in direct contact with the gate dielectric layer 150. The channel layer 140 may be disposed between the blocking pattern 148 and the gate dielectric layer 150. The blocking pattern 148 may be in contact with the first semiconductor pattern 146, which is a conductive layer, the channel layer 140, and the N-doped region 149.

As shown in FIG. 3, the first semiconductor pattern 146 and the N-doped region 149 may be electrically connected to each other at one end of the blocking pattern 148. As shown in FIG. 3, the first semiconductor pattern 146 and the channel layer 140 may be in contact with each other, and the channel layer 140 and the N-doped region 149 may be in contact with each other. Therefore, the first semiconductor pattern 146, the channel layer 140, and the N-doped region 149 may be electrically connected to one another. Therefore, as described separately below, an electron current applied to the channel structure CH may flow to the N-doped region 149, the channel layer 140, and the undoped region 1462 of the first semiconductor pattern 146, and a hole current transmitted through the common source electrode 112 for an erase operation may be applied to the P-doped region 1461 and undoped region 1462 of the first semiconductor pattern 146, and the channel layer 140.

FIG. 4 shows a flow direction of the hole current for erasing and a direction of the electron current flowing in channel inversion during a read operation in the same region as FIG. 3. As shown in a central portion of FIG. 4, the hole current may flow to the P-doped region 1461 and the undoped region 1462 of the first semiconductor pattern 146, and the channel layer 140. As shown in a right portion of FIG. 4, the electron current for the read operation may flow to the N-doped region 149 through the channel inversion of the undoped region 1462 of the first semiconductor pattern 146 and the channel layer 140. The flow of the hole current for erasing and a movement path of the electron current for the read operation may be independent from each other not to affect each other.

That is, the semiconductor element according to some embodiments may perform the erase by directly flowing the hole current from the P-doped region 1461 to the channel. Therefore, the semiconductor element according to these embodiments may perform a fast erase. An erase method that is operated by charging a channel capacitance may have a limitation in improving its efficiency due to a charging time and an erase time increased due to an increased charging time. However, the semiconductor element according to these embodiments may perform the erase by directly applying the hole current from the P-doped region 1461 to the channel, thus implementing the fast erase. However, the erase method that is performed by directly applying the hole current to the channel may have a complicated structure because it is necessary to separate a hole current path (hole path) for erasing and the electron current path (electron path) for the read operation. In addition, the electron path and the hole path may be broken due to misalignment during a process of forming the P-doped region and the N-doped region. However, in the semiconductor device according to this embodiment, the P-doped region 1461 may be disposed below each channel structure CH, and the N-doped region 149 may be disposed between the P-doped regions 1461. The blocking pattern 148 may be disposed between the P-doped region 1461 and the N-doped region 149 to thus separate the P-doped region 1461 and the N-doped region 149 from each other. Here, as shown in FIGS. 3 and 4, the electron path and the hole path may be independent from each other not to affect each other. In addition, in a method for manufacturing the semiconductor device according to these embodiments, the P-doped region 1461 may be formed in a self-alignment manner, thereby solving the problem in which the electron path and the hole path are broken due to the misalignment during the process of respectively forming the P-doped region 1461 and the N-doped region 149.

Hereinafter, the description describes the method for manufacturing the semiconductor device according to this embodiment.

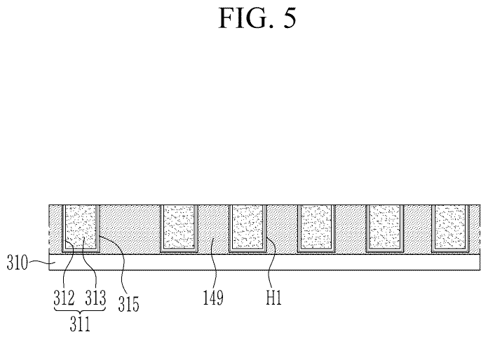

FIGS. 5 through 25 show the manufacturing process according to some embodiments of the present disclosure. For convenience of description, a method for manufacturing region A in FIG. 2 is described with reference to FIGS. 5 through 25.

First, referring to FIG. 5, an auxiliary substrate 310 may be prepared, and the auxiliary substrate 310 may be N-doped to form the N-doped region 149. An etch stopper 311 may then be formed on the auxiliary substrate 310. Here, an N doping material may be phosphorus (P) or arsenic (As), and is not limited thereto.

The etch stopper 311 may be formed by a method of forming a groove H1 in the auxiliary substrate 310 and filling the groove H1 of the auxiliary substrate 310. As shown in FIG. 5, the etch stopper 311 may include a first layer 312 and a second layer 313. The first layer 312 may be disposed along a surface of the groove H1 of the auxiliary substrate 310, and the second layer 313 may partially or completely fill the inside of the groove H1. However, this configuration is an example, and the present disclosure is not limited thereto. The etch stopper 311 may also be formed as one layer. The etch stopper 311 may include one or more of polycrystalline silicon, tungsten, TiN, and/or carbon. The first layer 312 may include TiN if the second layer 313 of the etch stopper 311 includes tungsten. In this case, the first layer 312 including TiN may prevent the diffusion of tungsten in the second layer 313. However, the etch stopper 311 may be formed of one layer if the etch stopper 311 includes polycrystalline silicon, TiN, or carbon.

In addition, as shown in FIG. 5, an interface layer 315 may be disposed between the etch stopper 311 and the auxiliary substrate 310. The interface layer 315 may include silicon oxide, and is not limited thereto. In some embodiments, the interface layer 315 may be omitted.

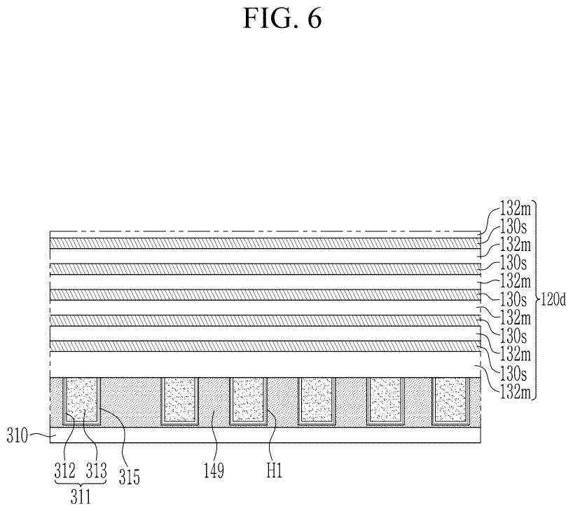

Next, referring to FIG. 6, the plurality of interlayer insulating layers 132m and a plurality of sacrificial insulating layers 130s may be alternately stacked on the auxiliary substrate 310 to thus form a first stack structure 120d. The interlayer insulating layer 132m may include silicon oxide, silicon nitride, silicon oxynitride, the low-k material, or the like; and the sacrificial insulating layer 130s may include at least one of silicon, silicon oxide, silicon carbide, and/or silicon nitride, and may be made of a material different from the interlayer insulating layer 132m. For example, the interlayer insulating layer 132m may include silicon oxide, and the sacrificial insulating layer 130s may include silicon nitride. The sacrificial insulating layer 130s may be a layer that is replaced with the gate electrode 130 (see FIG. 2) in a subsequent process. That is, the sacrificial insulating layer 130s may be formed to correspond to the portion where the gate electrode 130 (see FIG. 2) is to be formed.

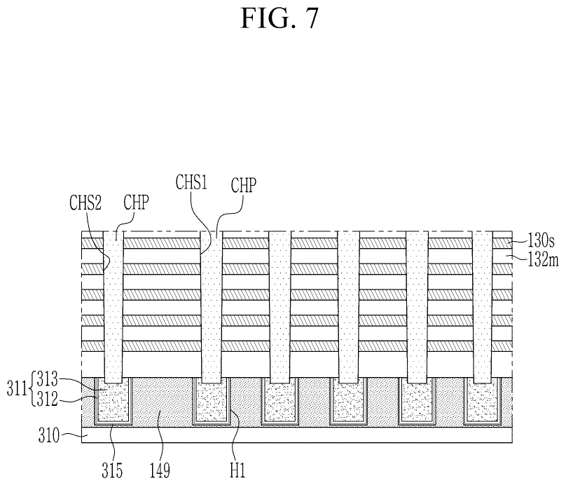

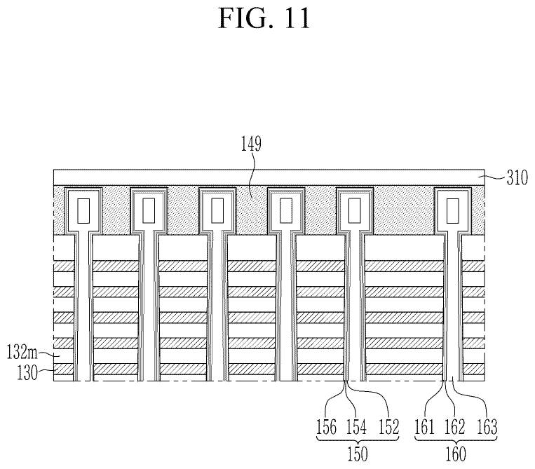

Next, referring to FIG. 7, the first stack structure 120d may be patterned to form a first sub-hole CHS1 and a second sub-hole CHS2 that pass through the first stack structure 120d by overlapping each of the etch stoppers 311. The first sub-hole CHS1 may be a region where the channel structure CH is to be formed, and the second sub-hole CHS2 may be a region where the separation structure 160 is to be formed. FIG. 11 shows the cross sections of the first sub-hole CHS1 and the second sub-hole CHS2. A planar shape of the first sub-hole CHS1 may be a circular shape similar to the channel structure CH shown in FIG. 1, and a planar shape of the second sub-hole CHS2 may be a shape in which the second sub-hole CHS2 extends in the second direction (Y direction) like the separation structure 160 shown in FIG. 1.

The first sub-hole CHS1 and the second sub-hole CHS2 may be formed by overlapping the etch stopper 311, and a portion of the etch stopper 311 may be etched due to the formation of the first sub-hole CHS1 and the second sub-hole CHS2. In this step, each of the first sub-hole CHS1 and the second sub-hole CHS2 may be partially or completely filled with a sacrificial film CHP. The sacrificial film CHP filling each of the first sub-hole CHS1 and the second sub-hole CHS2 may include polysilicon or a carbon-based material. However, the material of the sacrificial film CHP is not limited thereto, and may be changed in various ways.

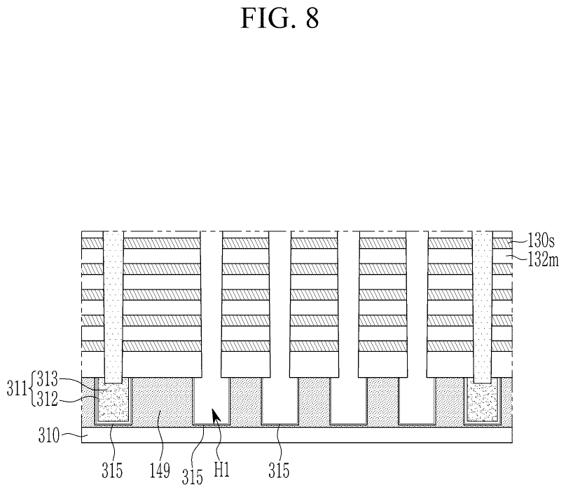

Next, referring to FIG. 8, the sacrificial film CHP and the etch stopper 311, filling the inside of the first sub-hole CHS1, may be removed. Here, the interface layer 315 may not be removed.

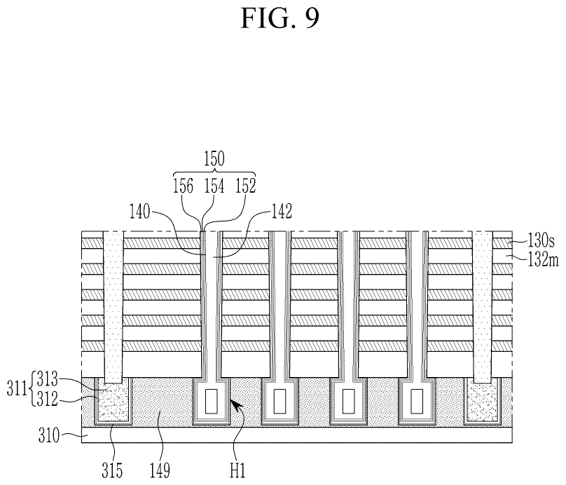

Next, referring to FIG. 9, the gate dielectric layer 150, the channel layer 140, and the core insulating layer 142 may be formed in the first sub-hole CHS1 from which the sacrificial film CHP and the etch stopper 311 are removed.

The gate dielectric layer 150 may include the tunneling layer 152, the charge storage layer 154, and the blocking layer 156. The tunneling layer 152 may include the insulating material (e.g., silicon oxide or silicon oxynitride) that allows the charge tunneling. The charge storage layer 154 may be used as the data storage region, and the charge storage layer 154 may include polycrystalline silicon, silicon nitride, or the like. The blocking layer 156 may include the insulating material that may prevent the undesirable charge inflow into the gate electrode 130. For example, the blocking layer 156 may include silicon oxide, silicon nitride, silicon oxynitride, the high-k material having a higher dielectric constant than silicon oxide, or the combination thereof. As an example, the tunneling layer 152 may include silicon oxide, the charge storage layer 154 may include silicon nitride, and the blocking layer 156 may include silicon oxide. However, this configuration is only an example, and the present disclosure is not limited thereto. If the blocking layer 156 includes silicon oxide and the interface layer 315 and the interface layer 315 also includes silicon oxide, a boundary therebetween may not be recognized. That is, as shown in FIG. 9, the boundary between the interface layer 315 and the blocking layer 156 may be not distinguished and may be recognized as one layer.

The channel layer 140 may include the semiconductor material, for example, monocrystalline silicon or polycrystalline silicon. The core insulating layer 142 may include the various insulating materials. For example, the core insulating layer 142 may include silicon oxide, silicon nitride, silicon oxynitride, or a combination thereof. The core insulating layer 142 may partially or completely fill a space in the first sub-hole CHS1. In the groove H1 where the etch stopper is removed, the core insulating layer 142 may not completely fill the groove H1, and a void may be formed.

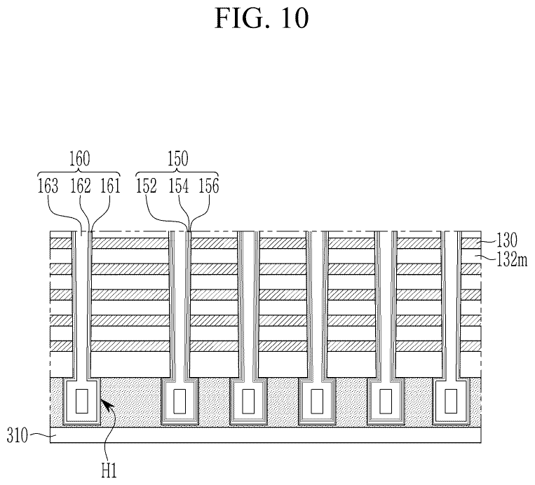

Next, referring to FIG. 10, the sacrificial film CHP and the etch stopper 311, filling the inside of the second sub-hole CHS2, may be removed, and the sacrificial insulating layer 130s may be selectively removed through the removed space to thus form the gate electrode 130. In detail, the sacrificial insulating layer 130s may be first removed, and the gate electrode 130 may be formed in a space from which the sacrificial insulating layer 130s is removed. That is, the sacrificial insulating layer 130s may be removed using an etching process, and a metal material such as tungsten (W), copper (Cu), aluminum (Al), or molybdenum (Mo) may then be deposited to thus form the gate electrode 130.

Next, the first layer 161, the second layer 162, and the third layer 163 may be formed in the second sub-hole CHS2. The first layer 161 may include silicon oxide, the second layer 162 may include silicon nitride, and the third layer 163 may include silicon oxide, which is only an example, and the present disclosure is not limited thereto. The first layer 161 filling the second sub-hole CHS2 may include the same material as the blocking layer 156 filling the first sub-hole CHS1, the second layer 162 filling the second sub-hole CHS2 may include the same material as the charge storage layer 154 filling the first sub-hole CHS1, and the third layer 163 filling the second sub-hole CHS2 may include the same material as the tunneling layer 152 filling the first sub-hole CHS1. However, this configuration is an example, and the present disclosure is not limited thereto.

The third layer 163 may partially or completely fill a space in the second sub-hole CHS2. In the groove H1 where the etch stopper is removed, the third layer 163 may not completely fill the groove H1, and the void may be formed.

Next, as shown in FIG. 11, the stack structure is flipped to dispose the auxiliary substrate 310 as an upper surface thereof.

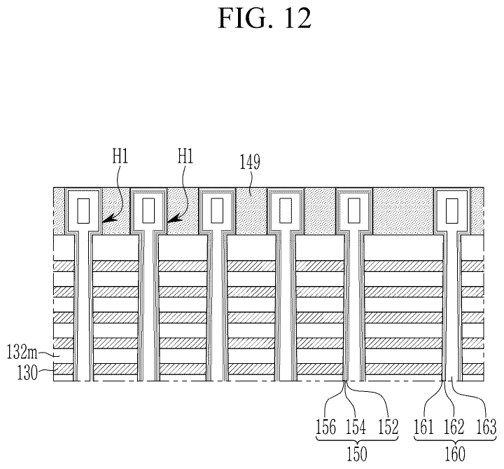

Next, referring to FIG. 12, the auxiliary substrate 310 and a portion of the N-doped region 149 may be removed. The auxiliary substrate 310 may be removed using a method of grinding an upper surface of the auxiliary substrate 310 and then removing the same by wet etching. However, this configuration is an example, and the present disclosure is not limited thereto. The auxiliary substrate 310 may be removed using various methods. The N-doped region may be removed using a chemical mechanical polishing (CMP) process after removing the auxiliary substrate 310. During this process, an upper surface of the groove H1 connected to the first sub-hole CHS1 and the second sub-hole CHS2 may be exposed. That is, as shown in FIG. 12, upper surfaces of the blocking layer 156 and the first layer 161, filling the first sub-hole CHS1 and the second sub-hole CHS2, may be exposed. The blocking layer 156 and the first layer 161 may each include silicon oxide.

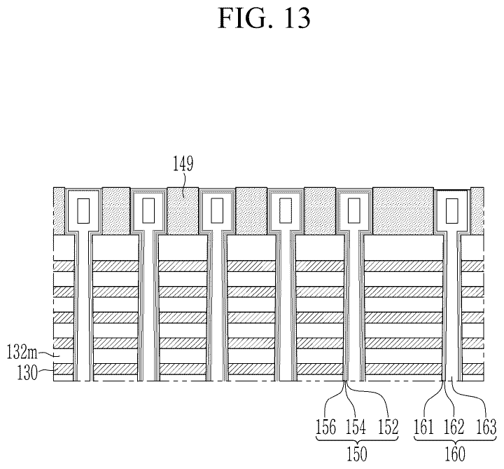

Next, referring to FIG. 13, the upper surfaces of the exposed blocking layer 156 and the first layer 161 may be removed. The blocking layer 156 and the first layer 161 may include the same material and may thus be removed using one process. During this process, upper surfaces of the second layer 162 and an charge storage layer 154 may be exposed.

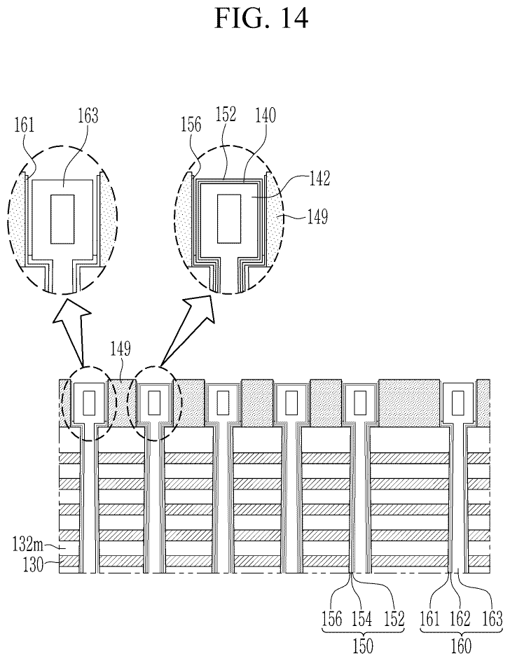

Next, referring to FIG. 14, the second layer 162 and the charge storage layer 154 may be removed. The second layer 162 and the charge storage layer 154 may each include silicon nitride. The second layer 162 and the charge storage layer 154 may include the same material and may thus be removed using one process.

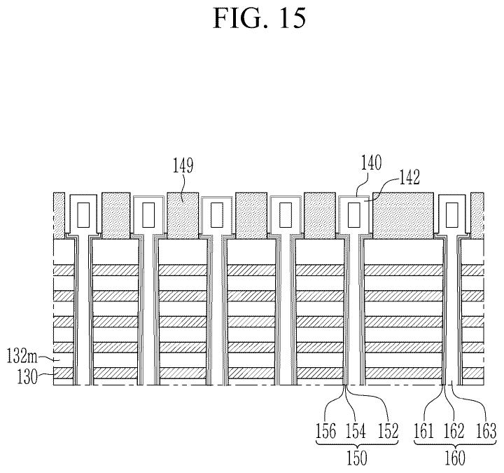

Next, referring to FIG. 15, a portion of the third layer 163 and the tunneling layer 152 may be removed. The third layer 163 and the tunneling layer 152 may include the same material and may thus be removed using one process. The third layer 163 and the tunneling layer 152 may each include silicon oxide. In this process, the thickness of the third layer 163 filling the groove H1 in an upper surface of the second sub-hole CHS2 may be reduced, and the tunneling layer 152 disposed in the groove H1 in an upper surface of the first sub-hole CHS1 may be removed. Therefore, the channel layer 140 may be exposed in the groove H1 in the upper surface of the first sub-hole CHS1.

In addition, the first and second layers 161 and 162, the tunneling layer 152, the charge storage layer 154, and the blocking layer 156 may be removed in the previous step, and a void space may thus be formed between the N-doped region 149 and the channel layer 140 and between the N-doped region 149 and the third layer 163.

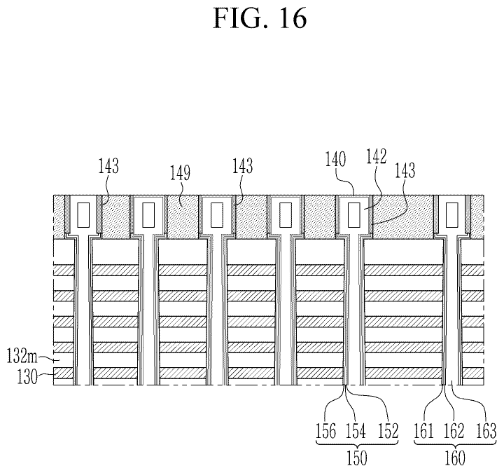

Referring to FIG. 16, a first undoped silicon layer 143 may be formed in the space between the N-doped region 149 and the channel layer 140. The first undoped silicon layer 143 may be formed on an entire upper portion of the structure, and the CMP process may then be performed to thus form the first undoped silicon layer 143 in the space between the N-doped region 149 and the channel layer 140 and the space between the N-doped region 149 and the third layer 163.

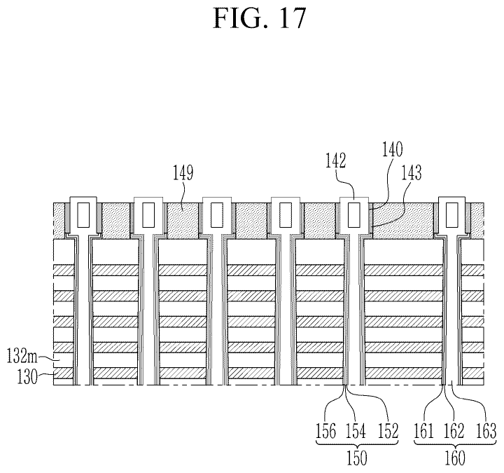

Next, referring to FIG. 17, silicon may be partially etched. Here, the exposed channel layer 140, N-doped region 149, and first undoped silicon layer 143 may all include silicon and may thus be etched simultaneously. As shown in FIG. 17, an upper surface of the channel layer 140 may be partially etched, and the N-doped region 149 and the first undoped silicon layer 143 may be partially etched to reduce their thicknesses. Therefore, as shown in FIG. 17, the third layer 163 and the core insulating layer 142, filling the groove H1, may protrude.

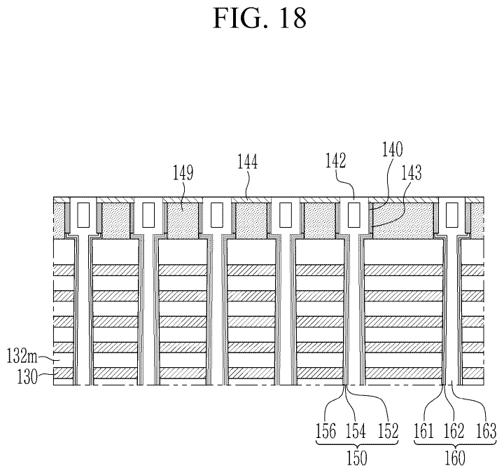

Next, referring to FIG. 18, a capping layer 144 may be formed. The capping layer 144 may include silicon nitride, and is not limited thereto. As shown in FIG. 18, the capping layer 144 may fill a space between the protruding core insulating layer 142 and third layer 163. The capping layer 144 having this shape may be formed by depositing the capping layer 144 on the entire surface of the structure and then performing the CMP process.

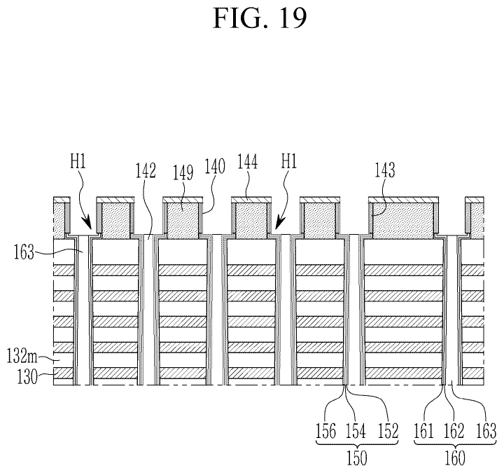

Next, referring to FIG. 19, the third layer 163 and the core insulating layer 142, filling the groove H1, may be removed. Here, the third layer 163 and the core insulating layer 142 may include the same material and may thus be removed using one process. In detail, the third layer 163 and the core insulating layer 142 may each include silicon oxide. Through this process, the groove H1 where the etch stopper is disposed may be exposed as an empty space. This space may be a region where the first semiconductor pattern is formed, as described below.

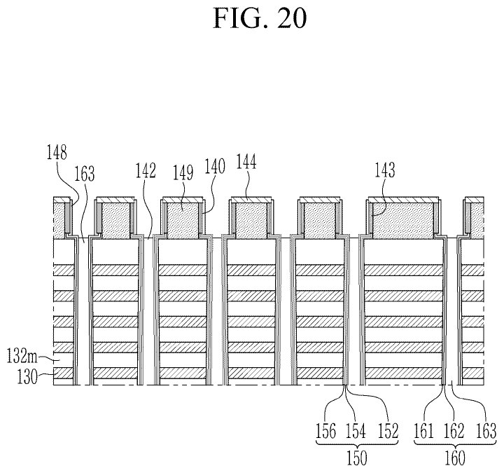

Next, referring to FIG. 20, the blocking pattern 148 may be formed on a sidewall of the groove H1. The blocking pattern 148 may include silicon oxide or silicon nitride. As shown in FIG. 20, the blocking pattern 148 may be formed on the side wall of the groove H1. The blocking pattern 148 may be formed through an etching process performed after forming the blocking pattern 148 on the entire surface of the structure. In this process, the third layer 163 and the core insulating layer 142, which include the same material as the blocking pattern, for example, silicon oxide, may be partially etched. Therefore, as shown in FIG. 20, the third layer 163 and the core insulating layer 142 may be etched at a bottom surface of the groove H1 to thus form a height difference.

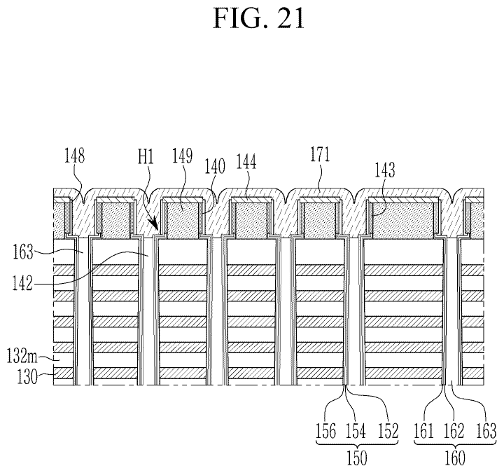

Next, referring to FIG. 21, a second undoped silicon layer 171 may be formed. As shown in FIG. 21, the second undoped silicon layer 171 may be disposed on the entire surface of the structure and fill the groove H1. Here, the second undoped silicon layer 171 formed in the groove H1 may not have a flat upper surface due to the height difference of the groove H1. The second undoped silicon layer 171 formed in this step may be amorphous.

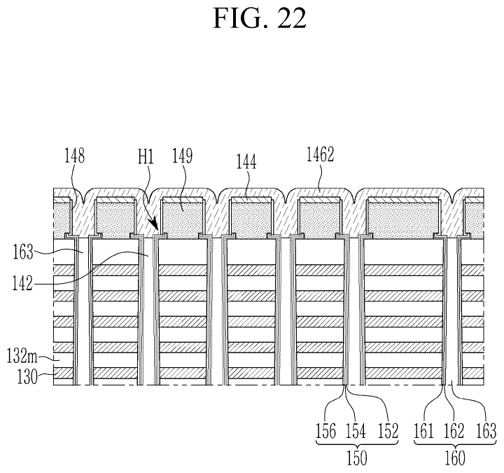

Next, referring to FIG. 22, the second undoped silicon layer 171 and the first undoped silicon layer 143 formed in the previous step may be irradiated with a laser to thus be crystallized. In this step, the second undoped silicon layer 171 may be crystallized to thus form the undoped region 1462.

In this step, the laser irradiation may be performed at a temperature of 1100 to 1300 degrees Celsius. This temperature may be in a temperature range where amorphous silicon may be crystallized. The amorphous silicon may become crystalline and have a semiconductor feature by the laser irradiation.

In the laser irradiation process, the first undoped silicon layer 143 may be in contact with the N-doped region 149, thus causing diffusion of the N-doped region 149. In addition, the channel layer 140 disposed on the side of the N-doped region 149 may also include silicon, thus causing the diffusion of the N-doped region 149. Therefore, a portion of the channel layer 140 and the first undoped silicon layer 143 may also be N-doped by the diffusion, thus forming one N-doped region 149. That is, as shown in FIG. 22, the N-doped region 149 may be expanded in this step.

However, the blocking pattern 148 may be disposed between the first undoped silicon layer 143 and the undoped region 1462, thus preventing the diffusion of N dopant into the undoped region 1462.

As shown in FIG. 22, due to the expansion of the N-doped region 149 caused by the diffusion of the N dopant, the N-doped region 149 and the channel layer 140 may be in contact with each other, and the channel layer 140 and the undoped region 1462 may be in contact with each other. This contact may lead to a movement path of electrons. FIG. 22 separately shows the channel layer 140 and the undoped region 1462. However, a boundary between the channel layer 140 and the undoped region 1462 may not be distinguished if both the channel layer 140 and the undoped region 1462 include silicon. Therefore, it may be recognized that the N-doped region 149 and the undoped region 1462 are in direct contact with each other, which may lead to the movement path of the electrons. Even if the channel layer 140 is separately recognized as being distinguished from the undoped region 1462 and the N-doped region 149, the channel layer 140 may also have a conductive property, which may thus lead to the movement path of the electrons.

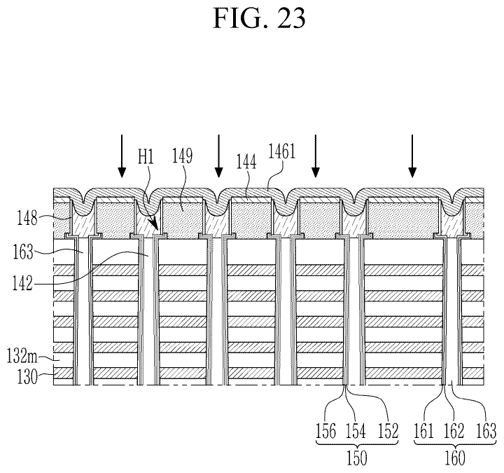

Next, referring to FIG. 23, P may be doped into the undoped region 1462. Here, a P doping material may be boron, and is not limited thereto. In this process, the capping layer 144 may be disposed on an upper part of the N-doped region 149, thus preventing the doping into the N-doped region 149. Referring to FIG. 23, the P-doped region 1461 may be formed on an upper surface of the undoped region 1462 by the P doping. Due to the height difference in the groove H1, the undoped region 1462 may not be uniformly formed on an upper part of the groove H1. Therefore, the P-doped region 1461 in the groove H1 may also be formed into a curved surface as shown in FIG. 23.

A laser annealing process may be performed after the P doping. Here, the laser annealing process may be performed at a temperature of 700 to 900 degrees Celsius. The temperature of the laser annealing process in this step may be lower than a laser irradiation temperature in the crystallization step in FIG. 22 above. The laser irradiation in FIG. 22 above may be performed to melt amorphous silicon and then crystallizes the same, thus requiring a high temperature. However, the laser annealing process in this step may be performed to activate P-doped silicon, thus eliminating a need for such a high temperature.

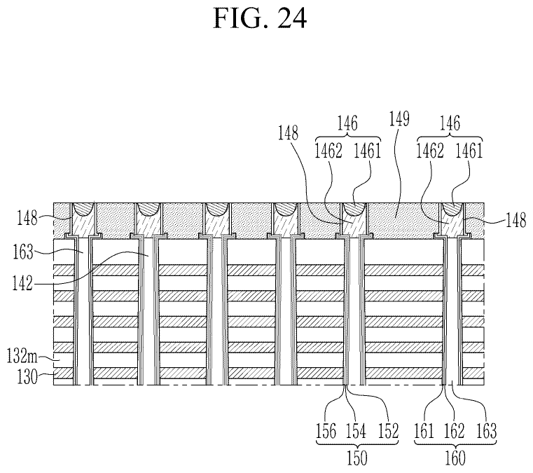

Next, referring to FIG. 24, an upper surface of the structure may be etched using the CMP process. In this process, the capping layer 144 may be removed. As shown in FIG. 24, an upper surface of the N-doped region 149 may be exposed through the etching process. In addition, an upper surface of the P-doped region 1461 in the groove may also be exposed. The blocking pattern 148 may be disposed between the N-doped region 149 and the P-doped region 1461. The undoped region 1462 and the channel layer 140 may be disposed below the P-doped region 1461, and may be in contact with the N-doped region 149 below the blocking pattern 148 as described above. Therefore, movement paths of the electrons and the hole current may be formed.

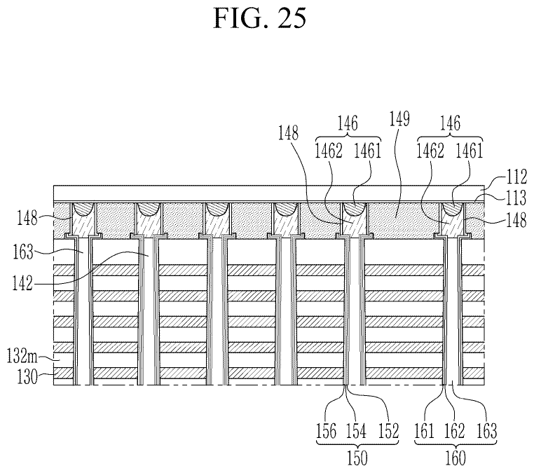

Next, referring to FIG. 25, the common source electrode 112 may be formed. As shown in FIG. 25, the common source electrode-interface layer 113 may be first formed, and the common source electrode 112 may then be formed. However, the configuration of the common source electrode-interface layer 113 is selective, and may be omitted in some embodiments.

This manufacturing method may be used to manufacture the semiconductor device in which the P-doped region 1461 is disposed at the bottom of each channel structure CH, the N-doped region 149 is disposed between the respective P-doped regions 1461, and the blocking pattern 148 is disposed between the P-doped region 1461 and the N-doped region 149. The semiconductor device having this shape may effectively perform the bulk erase operation, and the hole path for erasing and the movement path of the electron current for the read operation may be independent from each other not to affect each other. In addition, each of the P-doped region 1461 and the N-doped region 149 may be formed in the self-alignment manner, thereby solving the problem in which the electron path and the hole path are broken due to the misalignment during the process of forming the P-doped region and the N-doped region.

The following description describes in detail an example of the electronic system including the semiconductor device described above.

FIG. 26 is a view schematically showing an electronic system including a semiconductor device according to some embodiments.

Referring to FIG. 26, the electronic system 1000 according to some embodiments may include the semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive device (SSD), a universal serial bus (USB), a computing system, a medical device, or a communication device, including one or more semiconductor devices 1100.

The semiconductor device 1100 may be the nonvolatile memory device, for example, the NAND flash memory device described above. The semiconductor device 1100 may include the first structure 1100F and the second structure 1100S disposed on the first structure 1100F. In some embodiments, the first structure 1100F may be disposed next to or on the second structure 1100S. The first structure 1100F may be the peripheral circuit structure including a decoder circuit 1110, a page buffer 1120, and a logic circuit 1130. The second structure 1100S may be the memory cell structure including a bit line BL, the common source line CSL, a word line WL, first and second gate upper lines UL1 and UL2, first and second gate lower lines LL1 and LL2, and a memory cell string CSTR between the bit line BL and the common source line CSL.

In the second structure 1100S, each of the memory cell strings CSTR may include the lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously modified in some embodiments.

In some embodiments, the lower transistors LT1 and LT2 may include ground select transistors, and the upper transistors UT1 and UT2 may include string select transistors. The first and second gate lower lines LL1 and LL2 may respectively be gate lines of the lower transistors LT1 and LT2. The word line WL may be a gate line of the memory cell transistor MCT, and gate upper lines UL1 and UL2 may respectively be gate lines of the upper transistors UT1 and UT2.

The common source line CSL, the first and second gate lower lines LL1 and LL2, the word line WL, and the first and second gate upper lines UL1 and UL2 may each be electrically connected with the decoder circuit 1110 through a first connection wiring 1115 extending from the inside of the first structure 1100F to the second structure 1100S. The bit line BL may be electrically connected to the page buffer 1120 through a second connection wiring 1125 extending from the inside of the first structure 1100F to the second structure 1100S.

In the first structure 1100F, the decoder circuit 1110 and the page buffer 1120 may perform control operations on at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending from the inside of the first structure 1100F to the second structure 1100S.

The controller 1200 may include a processor 1210, a NAND controller 1220, and a host interface 1230. According to some embodiments, the electronic system 1000 may include the plurality of semiconductor devices 1100, in which case the controller 1200 may control the plurality of semiconductor devices 1100.

The processor 1210 may control overall operations of the electronic system 1000 including the controller 1200. The processor 1210 may be operated based on a predetermined firmware, and may access to the semiconductor device 1100 by controlling the NAND controller 1220. The NAND controller 1220 may include a NAND interface 1221 that processes its communication with the semiconductor device 1100.

Through the NAND interface 1221, the NAND controller 1220 may transmit a control instruction for controlling the semiconductor device 1100, data to be written to the memory cell transistor MCT of the semiconductor device 1100, data to be read from the memory cell transistor MCT of the semiconductor device 1100, or the like. The host interface 1230 may function to provide communication between the electronic system 1000 and an external host. When receiving the control instruction from the external host through the host interface 1230, the processor 1210 may control the semiconductor device 1100 in response to the control instruction.

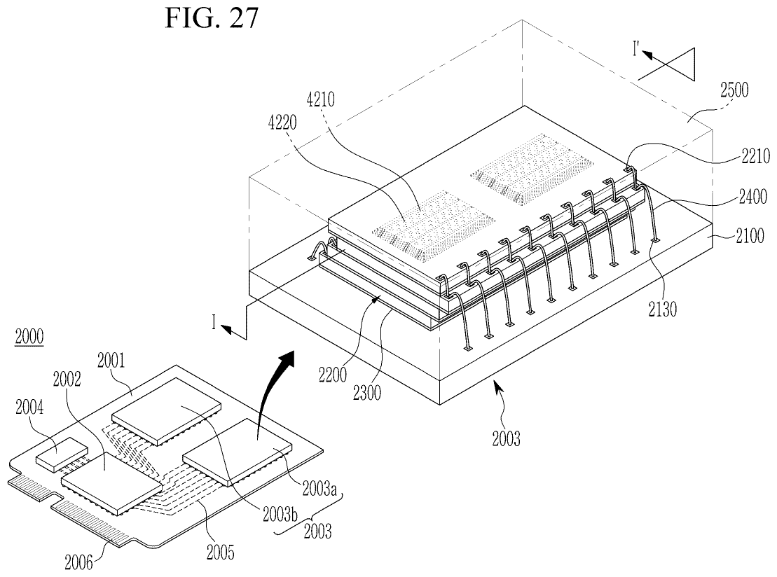

FIG. 27 is a perspective view schematically showing the electronic system including a semiconductor device according to some embodiments. FIG. 28 shows some embodiments of a semiconductor package 2003 of FIG. 27, and conceptually shows a region cut along line I-I′ of the semiconductor package 2003 in FIG. 27.

Referring to FIG. 27, an electronic system 2000 according to some embodiments may include a main substrate 2001, a controller 2002 mounted on the main substrate 2001, one or more semiconductor packages 2003 and a dynamic random access memory (DRAM) 2004. The semiconductor package 2003 and the DRAM 2004 may be connected to the controller 2002 by a wiring pattern 2005 formed on the main substrate 2001.

The main substrate 2001 may include a connector 2006 including a plurality of pins coupled to the external host. The number and arrangement of the plurality of pins in the connector 2006 may be changed based on a communication interface between the electronic system 2000 and the external host. In some embodiments, the electronic system 2000 may communicate with the external host based on any one of the interfaces such as the universal serial bus (USB), a peripheral component interconnect (PCI)-express, a serial advanced technology attachment (SATA), or an M-physostigmine (Phy) for a universal flash storage (UFS). In some embodiments, the electronic system 2000 may be operated by power supplied from the external host through the connector 2006. The electronic system 2000 may further include a power management integrated circuit (PMIC) that distributes power supplied from the external host to the controller 2002 and the semiconductor package 2003.

The controller 2002 may write data to the semiconductor package 2003 or read data from the semiconductor package 2003, and improve an operation speed of the electronic system 2000.

The DRAM 2004 may be a buffer memory to mitigate a speed difference between the semiconductor package 2003, which is a data storage space, and the external host. The DRAM 2004 included in the electronic system 2000 may also be operated as a type of a cache memory, and may provide a space for temporarily storing data during an operation of controlling the semiconductor package 2003. If the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be the semiconductor package including a plurality of semiconductor chips 2200. Each of the first and second semiconductor packages 2003a and 2003b may include a package substrate 2100, a semiconductor chip 2200 disposed on the package substrate 2100, an adhesive layer 2300 disposed on a lower surface of each semiconductor chip 2200, a connection structure 2400 electrically connecting the semiconductor chip 2200 and the package substrate 2100 to each other, and a molding layer 2500 disposed on the package substrate 2100 and covering the semiconductor chip 2200 and the connection structure 2400.

The package substrate 2100 may be a printed circuit board including a package upper pad 2130. Each semiconductor chip 2200 may include an input/output pad 2210. The input/output pad 2210 may correspond to the input/output pad 1101 in FIG. 26.

Each semiconductor chip 2200 may include a gate stack structure 4210 and a channel structure 4220. The semiconductor chip 2200 may include the semiconductor device described with reference to the drawings above.

In some embodiments, the connection structure 2400 may be a bonding wire electrically connecting the input/output pad 2210 and the package upper pad 2130 to each other. Accordingly, the semiconductor chips 2200 of each of the first and second semiconductor packages 2003a and 2003b may be electrically connected to each other by a bonding wire method, and may be electrically connected to the package upper pad 2130 of the package substrate 2100. According to some embodiments, the semiconductor chips 2200 of each of the first and second semiconductor packages 2003a and 2003b may also be electrically connected to each other by a connection structure including a through electrode (through silicon via, TSV), instead of the bonding wire type connection structure 2400.

In some embodiments, the controller 2002 and the semiconductor chip 2200 may be included in one package. For example, the controller 2002 and the semiconductor chip 2200 may be mounted on a separate interposer substrate different from the main substrate 2001, and the controller 2002 and the semiconductor chip 2200 may be connected to each other by a wiring formed on the interposer substrate.

Referring to FIG. 28, in the semiconductor package 2003, the package substrate 2100 may be the printed circuit board. The package substrate 2100 may include a package substrate body part 2120, a package upper pad 2130 disposed on an upper surface of the package substrate body part 2120, a package lower pad 2125 disposed on a lower surface of the package substrate body part 2120 or exposed through the lower surface, and an internal wiring 2135 electrically connecting the package upper pad 2130 and the package lower pad 2125 to each other in the package substrate body part 2120. The package upper pad 2130 may be electrically connected to the connection structure 2400. The package lower pad 2125 may be connected to the wiring pattern 2005 of the main substrate 2001 included in the electronic system 2000 through a conductive connector 2800, as shown in FIG. 27.

Referring to FIG. 28, in the semiconductor package 2003, each semiconductor chip 2200 may include a semiconductor substrate 4010, a first structure 4100 disposed on the semiconductor substrate 4010, and a second structure 4200 disposed on the first structure 4100 and bonded to the first structure 4100 by a wafer bonding method.

The first structure 4100 may include a peripheral circuit region including a peripheral wiring 4110 and a first bonding structure 4150. The second structure 4200 may include a common source line 4205, the gate stack structure 4210 disposed between the common source line 4205 and the first structure 4100, a channel structure 4220 and a separation structure 4230, passing through the gate stack structure 4210, and a second bonding structure 4250 electrically connected to each word line of the channel structure 4220 and the gate stack structure 4210. For example, the second bonding structure 4250 may be electrically connected to each of the channel structure 4220 and the word line WL through a bit line 4240 electrically connected to the channel structure 4220 and a gate connection wiring electrically connected to the word line WL.

As shown in FIG. 28, the second structure 4200 may include the 2-1 structure 4200a and the 2-2 structure 4200b, which are bonded to each other. The 2-1 structure 4200a and the 2-2 structure 4200b may be bonded to each other while being in contact with each other. A portion where the 2-1 structure 4200a and the 2-2 structure 4200b are bonded to each other may be made of, for example, copper (Cu).

The first bonding structure 4150 of the first structure 4100 and the second bonding structure 4250 of the second structure 4200 may be bonded to each other while being in contact with each other. A portion where the first bonding structure 4150 and the second bonding structure 4250 are bonded to each other may be made of, for example, copper (Cu).

According to some embodiments, the semiconductor device may be manufactured in such a way that in the semiconductor chip 2200 or the semiconductor device, the P-doped region 1461 is disposed at the bottom of each channel structure CH, the N-doped region 149 is disposed between the respective P-doped regions 1461, and the blocking pattern 148 is disposed between the P-doped region 1461 and the N-doped region 149. The semiconductor device having this shape may effectively perform the bulk erase operation, and the movement path of the hole current for erasing and the movement path of the electron current for the read operation may be independent from each other not to affect each other.

Each semiconductor chip 2200 may further include the input/output pad 2210 and an input/output connection wiring 4265 disposed below the input/output pad 2210. The input/output connection wiring 4265 may be electrically connected to a portion of the second bonding structure 4250.

According to some embodiments, in the semiconductor package 2003, the plurality of semiconductor chips 2200 may be electrically connected to each other by the connection structure 2400 in a form of the bonding wire. As another example, the plurality of semiconductor chips 2200 or a plurality of portions included in the same may be electrically connected to each other by the connection structure including the through electrode.

While this disclosure has been described in connection with what is presently considered to be practical embodiments, it is to be understood that the disclosure is not limited to the disclosed embodiments, but is intended to cover various modifications and equivalent arrangements included within the scope of the appended claims.

What is claimed is:

1. A semiconductor device comprising:
a gate stack structure including a plurality of interlayer insulating layers and a plurality of gate electrodes that are alternately stacked;
a channel structure that extends into the gate stack structure;
a plurality of first semiconductor patterns at one end of the channel structure and each of the plurality of first semiconductor patterns including a P-doped region and an undoped region;
an N-doped region between adjacent ones of the first semiconductor patterns;
a blocking pattern between the P-doped region and the N-doped region; and
a common source electrode on respective surfaces of the plurality of first semiconductor patterns and the N-doped region.

2. The semiconductor device of claim 1, wherein the undoped region is between the P-doped region and the channel structure, and
wherein the undoped region is in contact with the channel structure.

3. The semiconductor device of claim 1, wherein a cross section of the P-doped region includes a curved surface.

4. The semiconductor device of claim 1, wherein the P-doped region has a plan view dimension that is less than or equal to a plan view dimension of a widest portion of the channel structure.

5. The semiconductor device of claim 1, wherein the P-doped region has a plan view dimension that is greater than a plan view dimension of a region of the channel structure that is in contact with a respective one of the plurality of first semiconductor patterns.

6. The semiconductor device of claim 1, wherein the blocking pattern includes silicon oxide or silicon nitride.

7. The semiconductor device of claim 1, wherein the channel structure includes a channel layer and a gate dielectric layer, and
wherein the gate dielectric layer and the blocking pattern are spaced apart from each other.

8. The semiconductor device of claim 7, wherein the N-doped region and the channel layer are in contact with each other, and
wherein the channel layer and the undoped region are in contact with each other.

9. The semiconductor device of claim 1, wherein the P-doped region and the N-doped region are spaced apart from each other.

10. The semiconductor device of claim 1, further comprising:
a separation structure that extends into the gate stack structure; and
a first semiconductor pattern at one end of the separation structure and including the P-doped region and the undoped region.

11. A semiconductor device comprising:
a substrate including an N-doped region and a plurality of first semiconductor patterns in the N-doped region;
a gate stack structure including a plurality of interlayer insulating layers and a plurality of gate electrodes that are alternately stacked on the substrate; and
a channel structure that extends into the gate stack structure and overlaps the first semiconductor pattern in a direction perpendicular to the substrate,
wherein the first semiconductor pattern includes a P-doped region and an undoped region, and
wherein the first semiconductor pattern includes a blocking pattern between the P-doped region and the N-doped region.

12. The semiconductor device of claim 11, wherein the undoped region is between the P-doped region and the channel structure, and
wherein the undoped region is in contact with the channel structure.

13. The semiconductor device of claim 11, wherein a cross section of the P-doped region includes a curved surface.

14. The semiconductor device of claim 11, wherein the P-doped region has a plan view dimension that is less than or equal to a plan view dimension of a widest portion of the channel structure, and
wherein the plan view dimension of the P-doped region is greater than a plan view dimension of a narrowest portion of the channel structure.

15. The semiconductor device of claim 11, wherein the blocking pattern includes silicon oxide or silicon nitride.

16. The semiconductor device of claim 11, wherein the channel structure includes a channel layer and a gate dielectric layer, and
wherein the gate dielectric layer and the blocking pattern are spaced apart from each other.

17. The semiconductor device of claim 16, wherein the N-doped region and the channel layer are in contact with each other, and
wherein the channel layer and the undoped region are in contact with each other.

18. An electronic system comprising:
a main substrate;
a semiconductor device on the main substrate; and
a controller on the main substrate and electrically connected to the semiconductor device,
wherein the semiconductor device comprises:
a gate stack structure including a plurality of interlayer insulating layers and a plurality of gate electrodes that are alternately stacked,
a channel structure that extends into the gate stack structure,
a plurality of first semiconductor patterns at one end of the channel structure, and each of the plurality of first semiconductor patterns including a P-doped region and an undoped region,
an N-doped region between adjacent ones of the first semiconductor patterns,
a blocking pattern between the P-doped region and the N-doped region, and
a common source electrode on respective surfaces of the plurality of first semiconductor patterns and the N-doped region.

19. The electronic system of claim 18, wherein the P-doped region has a plan view dimension that is less than or equal to a plan view dimension of a widest portion of the channel structure, and
wherein the plan view dimension of the P-doped region is greater than a plan view dimension of a region of the channel structure that is in contact with a respective one of the plurality of first semiconductor patterns.

20. The electronic system of claim 18, wherein the channel structure includes a channel layer and a gate dielectric layer,
wherein the N-doped region and the channel layer are in contact with each other, and
wherein the channel layer and the undoped region are in contact with each other.
